(19) United States
(12) Patent Application Publication
(10) Pub. No.: US 2004/0098654 A1
(43) Pub. Date: May 20, 2004

(54) FIFO memory with ECC function

(76) Inventors: Der-Kant Cheng, Taipei (TW); Jiou-Sz Shen, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/065,737

(22) Filed: Nov. 14, 2002

(51) Int. Cl. H03M 13/00; G11C 29/00

(52) U.S. Cl. 714/758

(57) ABSTRACT

A first-in-first-out (FIFO) semiconductor memory with error correction code (ECC) function is provided. A check code is generated by computing an input data in an ECC encoder unit before the input data is written into the FIFO memory. The check code is stored inside the FIFO memory together with the input data. The error bits in the input data will be checked and corrected using the check code stored inside the FIFO memory while the input data is read from the FIFO memory so that input data are unaffected by noise and data integrity is maintained.

### BACKGROUND OF INVENTION

1. Field of Invention

The present invention relates to a first-in-first-out (FIFO) memory. More particularly, the present invention relates to a first-in-first-out memory with error correction code (ECC) function.

2. Description of Related Art

Due to rapid advance in electronic technologies, various types of electronic devices including storage area network, in a wireless case station, router communication and medical image processor or the 3D simulator are used regularly. All these electrical devices transfer a large volume of data at a fast transfer and hence most of the devices adapt first-in-first-out memory (FIFO for short) to serve as a data transmission memory. The FIFO memory receives data from a receiving port (terminal) and stores the data inside a memory unit. At the output port of the memory, data first written into the memory unit is retrieved first until all data within the memory unit are empty. However, as data are transmitted to or from the FIFO memory at a high transmission rate, surrounding noise such as cosmic rays or radio waves may affect the transmission and cause some data lost. When this happens, integrity of the data transmission is often compromised leading to a drop in overall transmission performance of the memory.

### SUMMARY OF INVENTION

Accordingly, one object of the present invention is to provide a first-in-first-out (FIFO) memory with error correction code (ECC) function capable of generating a check code based on current of transmission data through an encoder and storing the check code with the data in the FIFO memory. When the input data is read from the FIFO memory, the check code is used to check the correlation and correct any error bits so that integrity of the data transmission is ensured.

To achieve these and other advantages and in accordance with the purpose of the invention, as embodied and broadly described herein, the invention provides a first-in-first-out (FIFO) memory with error correction code function. The FIFO memory includes an error correction code encoder unit (ECC encoder unit), a FIFO memory circuit and an error correction code decoder unit (ECC decoder unit). The error correction code encoder unit receives the input data and generates a check code according to the input data. The FIFO memory stores the input data and the check code and outputs the input data and the check code following a first-in-first-out rule. The error correction code decode unit is coupled to the FIFO memory circuit for checking any bit errors using the stored input data and the check code. If a bit error is found in the input data and the error byte is within a correctable byte range, the error bit in the input data will be corrected before output.

In one embodiment of this invention, the FIFO memory circuit further includes a memory unit, a write control unit, a read control unit and a flag logic unit. The memory holds write-in input data and check code. The write control unit couples with the memory unit and has a write pointer for controlling the sequential writing of memory addresses of the input data and the check codes. The read control unit couples with the memory unit and has a read pointer for controlling the sequential reading of the memory addresses of input data and check codes. The flag logic unit couples with the write control unit and the read control unit for generating a memory full flag and a memory empty flag according to the value of the write pointer and the read pointer. The error correction code decode unit has the capacity to correct 1 bit of error and detects 2 bits of errors in an error byte.

The memory unit may also include a regular memory and a redundant memory. When a portion of the regular memory fails, the redundant memory may be used. In addition, the FIFO memory with the ECC function may further include a setting circuit for enabling the ECC function in the FIFO memory. The setting circuit may be implemented through an inverter and a multiplexer.

In brief, this invention provides a FIFO memory with ECC function that stores encoded check codes and input data before the input data are written into the memory. Through the check codes, error bits are found and corrected when input data are read. Hence, any data errors resulting from noise during a high-speed data transmission can be corrected and integrity of the data can be ensured

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a block diagram showing the pin positions of a module with error correction code function; and

FIG. 2 is a diagram showing various units within a first-in-first-out memory according to one preferred embodiment of this invention.

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

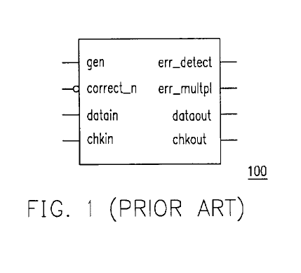

FIG. 1 is a block diagram showing the various pins in a DW_ecc module provided by Synopsys” Designware with error correction code (ECC) function. As shown in FIG. 1, the pins on the ECC function module 100 include gen, correct_n, datain, chkin, err_detect, err_multpl, dataout and chkout.

The pin gen is a pin for setting the ECC function module 100 into an ECC encoder unit or an ECC decoder unit. When gen=1, the ECC function module 100 serves as an ECC encoder unit. Conversely, when gen=0, the ECC function module 100 serves as an ECC decoder unit. When the ECC function module 100 is set to an ECC decoder unit, the pin correct₁₃ n is set to zero so that the error bit correction function in the decoder unit is enabled. The error bit correction function in the ECC function module 100 is capable of correcting a single error bit in a byte.

The pin datain is a pin for receiving input data. The width of each input data can be set to a value between 8 bits to 502 bits. In the following description, each input data is assumed to have a width of 72 bits. When the ECC function module 100 serves as an ECC encoder unit, that is, gen=1, the ECC function module 100 encodes the received input data to produce a check code. The check code is output via the chkout pin. The width of the check code ranges from 5 bits to 10 bits depending on the selection. In the following embodiment, the check code has an 8-bit width. On the other hand, when the ECC function module 100 serves as an ECC decoder unit, that is, gen=0 and correct_n=0, the input data and the previously encoded check code must be input into the ECC function module 100 via the chkin pin. According to the input data and the check code, the ECC function module 100 detects any error bit and corrects the error bit. The corrected input data and check code are output from the ECC module 100 via the pin dataout and the pin chkout respectively. Furthermore, when a single correctable error bit is found, the output pin err_detect is set. When two error bits are found, the output pin err₁₃ multpl is set. Hence, the ECC function module 100 is capable of correcting a single bit error only but capable of finding two bits of error in an error byte.

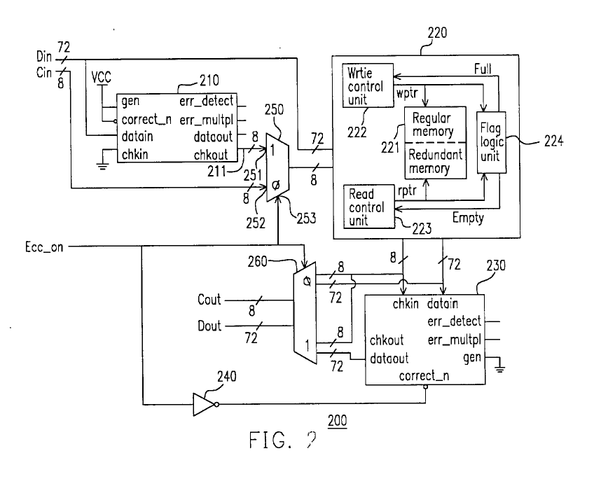

FIG. 2 is a diagram showing various units within a first-in-first-out memory according to one preferred embodiment of this invention. As shown in FIG. 2, the first-in-first-out (FIFO) memory 200 with ECC function includes an ECC encoder unit 210, a FIFO memory circuit 220 and an ECC decoder unit 230. To be able to enable or disable the ECC function in the FIFO memory 200, the FIFO memory 200 further includes a setting circuit comprising of an inverter 240 and a pair of multiplexers 250 and 260.

In FIG. 2, the pin gen in the ECC encoder unit 210 is set to 1. When the ECC encoder unit 210 receives a 72-bit input data Din, an 8-bit check code 211 is generated and output from the pin chkout. The check code 211 is input to one terminal 251 of the multiplexer 250. The other terminal 252 of the multiplexer 250 receives an input code Cin. By sending an enable signal Ecc_on to the selection terminal 253 of the multiplexer 250, the transfer of the input data Din and the check code 211 or the input code Cin into the FIFO memory circuit 220 can be selected.

In one preferred embodiment, the FIFO memory circuit 220 further includes a memory unit 221, a write control unit 222, a read control unit 223 and a flag logic unit 224. The memory unit 221 includes, for example, a regular memory and a redundant memory so that when the regular memory fails, the redundant memory may cut in to serve as a replacement. The memory unit 221 is capable of holding write-in input data Din and check codes 211 or input codes Cin. The write control unit 222 couples with the memory unit 221. The write control unit 222 has a write pointer wptr for controlling the writing sequence of memory addresses of the input data Din and the check codes 211 or the input codes Cin. The read control unit 223 also couples with the memory 221. The read control unit 223 has a read pointer rptr for controlling the reading sequence of the memory addresses of the input data Din and the check codes 211 or the input codes Cin. Obviously, the write pointer wptr and the read pointer rptr both follow the first-in-first-out rule. The flag logic unit 224 couples with the write control unit 222 and the read control unit 223 for generating a memory full flag and a memory empty flag according to the value in the write pointer wptr and the read pointer rptr. The memory full flag indicates the memory is full and the memory empty flag indicates the memory is empty.

In FIG. 2, the pin gen in the ECC decoder unit 230 is set to zero. If the enable signal Ecc₁₃ on is also set to one, the pin correct_n in the ECC decoder unit 230 receives a zero after inversion by the inverter 240 and hence enables the ECC function in the ECC decoder unit 230. When the ECC decoder unit 230 receives input data Din and check codes 211 from the datain pin and the chkin pin, the presence or absence of an error bit can be detected through the data input words Din and the check codes 211. When an error bit is found in the error checking and if the error byte is with a correctable byte range, corrected input data (Din) and check codes 211 will output from the dataout pin and the chkout pin respectively.

The multiplexer 250 is a selection device for inputting either the check codes 211 or the input codes Cin. Similarly, the multiplexer 260 is a selection device for outputting the corrected input data or uncorrected input data through the terminal Dout. When the enable signal Ecc_on is set to one, the corrected input data Din are output from the terminal Dout. When the enable signal Ecc_on is set to zero, the uncorrected input data Din are output from the terminal Dout. Since the FIFO memory 200 is able to hold an 80-bit width data when the ECC function is disabled, the input code Cin may also be carried by another 8 data bits of the input data Din. Hence, the multiplexer 260 is employed to redirect the input code Cin stored inside the memory unit 221 to the output terminal Cout. In other words, the 8-bit input data Din at the output terminal Cout and the 72-bit input data Din at the output terminal Dout combine to produce an 80-bit output data.

In the aforementioned embodiment, the DW_ecc module with ECC function provided by Synopsys” Designware is used as an example. However, anyone familiar with the technologies may incorporate the design in other systems including, for example, the Convolutional and Trellis, Reed-Solomon, Hamming, Glay and BoseChaudhuri-Hocquenhem (BCH) encoding/decoding scheme as well.

In summary, major advantages of this invention include:

1. The design prevents the loss of data due to noise when data are transmitted at high speed to or from the FIFO memory. Hence, data integrity is ensured and system performance is improved.

2. Built-in ECC functions may be deployed to assist error detection during fabrication. Hence, production yield is increased and the deployment of a FIFO memory with a higher storage capacity is possible.

3. Since the ECC function in an ECC function module can be enabled or disabled, the module is compatible with other products.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A first-in-first-out semiconductor memory with error correction code function, comprising:
an error correction code encoder unit for receiving an input data and generating a check code according to the input data;
a first-in-first-out memory circuit for holding the input data and the check code and outputting the input data and the check code according to the first write-in first read-out rule; and
an error correction code decoder unit coupled to the first-in-first-out memory circuit for finding error bits according to the input data and the check code such that if an error bit is found and if the error byte is within a correctable byte error range, the decoder unit outputs a corrected input data.

2. The first-in-first-out memory of claim 1, wherein the first-in-first-out memory circuit further includes:
a memory unit for holding input data and check codes;
a write control unit coupled to the memory unit, wherein the write control unit has a pointer for controlling the write-in sequence of the memory addresses of the input data and the check codes;
a read control unit coupled to the memory unit, wherein the read control unit has a pointer for controlling the read-out sequence of the memory addresses of the input data and the check codes; and
a flag logic unit coupled to the write control unit and the read control unit for setting up a memory full flag and a memory empty flag according to the value the write pointer and the read pointer.

3. The first-in-first-out memory of claim 1, wherein the memory unit further includes regular memory and redundant memory.

4. The first-in-first-out memory of claim 1, wherein the memory further includes a setting circuit for enabling or disabling the error correction code function in the first-in-first-out memory.

5. The first-in-first-out memory of claim 4, wherein the setting circuit is constructed using an inverter and a multiplexer.

6. The first-in-first-out memory of claim 1, wherein the correctable byte is one error bit.

7. The first-in-first-out memory of claim 1, wherein the error correction code decoder unit is capable of finding two error bits in an error byte.
